(19) United States
(12) Patent Application Publication
(10) Pub. No.: US 2019/0206741 A1
(43) Pub. Date: Jul. 4, 2019

(54) METHOD AND STRUCTURE TO ELIMINATE SUBSTRATE COUPLING IN COMMON DRAIN DEVICES

(71) Applicant: TEXAS INSTRUMENTS INCORPORATED, Dallas, TX (US)

(72) Inventors: Anindya PODDAR, Sunnyvale, CA (US); Usman Mahmood CHAUDHRY, McKinney, TX (US); Tran Kiet THU, Pano, TX (US); Mahmud Halim CHOWDHURY, Addison, TX (US); Peter SMEYS, San Jose, CA (US)

(21) Appl. No.: 15/858,862

(22) Filed: Dec. 29, 2017

(51) Int. Cl. H01L 21/8234; H01L 21/762; H01L 21/304; H01L 27/088; H01L 23/31

(52) U.S. Cl. CPC H01L 21/823481; H01L 21/76224; H01L 21/823487; H01L 21/823425; H01L 27/088; H01L 23/3178; H01L 21/3043

(57) ABSTRACT

In one aspect of the disclosure, an integrated circuit is disclosed. The integrated circuit includes a first FET device formed on a substrate having a first source, a first gate, and a first channel. The first channel is formed in the substrate, connecting the first source to a common drain. The integrated circuit also includes a second FET device formed on the substrate having a second source, a second gate, and a second channel. The second channel is formed in the substrate, connecting the second source to the common drain. A trench is formed in the substrate between the first channel and the second channel.

### BACKGROUND

This disclosure relates generally to the field of semiconductors, and more specifically, it discusses fabrication of multiple transistors on a single die.

The scaling of features in integrated circuits (ICs) is one of the primary forces behind an ever-growing semiconductor industry. Smaller features within ICs allow for an increased density of functional units in electrical devices, and therefore, facilitates achievement of higher capacities. For example, when more space is available on an electronic device due to shrinking sizes of transistors, the available space can be used to increase the number of memory devices and battery units. The further reduction in scale of the ICs, however, is not without a challenge and the need to optimize the performance of each device becomes increasingly significant.

In more advanced semiconductor processing techniques, multiple Field-Effect Transistors (FETs) may be formed within a single semiconductor die. Presence of multiple FET devices on a single die provides a smaller footprint on the ICs. NexFET™ devices are an example of multiple FET devices formed on a substrate sharing a common drain. In such a small scale and close proximity of the elements, reducing undesirable leakage is a challenge. Therefore, there is a need for improvements on the design and manufacturing of such transistors in order to improve their functionality.

### SUMMARY

In one aspect of the disclosure, an integrated circuit is disclosed. The integrated circuit includes a first FET device formed on a substrate having a first source, a first gate, and a first channel. The first channel is formed in the substrate, connecting the first source to a common drain. The integrated circuit also includes a second FET device formed on the substrate having a second source, a second gate, and a second channel. The second channel is formed in the substrate, connecting the second source to the common drain. A trench is formed in the substrate between the first channel and the second channel.

In another aspect of the disclosure, a method for fabricating semiconductor dies is disclosed. One or more semiconductor dies are formed on a wafer. At least one semiconductor die of the one or more semiconductor dies includes two FET devices and two channels associated with each FET devices. The wafer is thinned by performing backgrinding operation. A trench is created by partially dicing the wafer between the two channels of the at least one semiconductor die. The wafer is singulated to separate the at least one semiconductor die from the rest of the one or more semiconductor dies. The at least one semiconductor die is attached to a supporting case.

In yet another aspect of the disclosure, a semiconductor package is disclosed. The semiconductor package comprises a semiconductor die, wherein the semiconductor die includes two FET devices and two channels associated with each FET devices. A lead frame is attached to the semiconductor die through a layer of die attach. A trench is formed between the two FET devices, wherein trench at least partially isolates the two channels of the semiconductor die.

### BRIEF DESCRIPTION OF THE DRAWINGS

For a detailed description of various examples, reference will now be made to the accompanying drawings in which:

FIG. 1A shows a cross-sectional view of a semiconductor die including two field-effect transistor (FET) devices according to an implementation of the disclosure.

FIG. 1B shows a top view of a semiconductor die including two FET devices according to an implementation of the disclosure.

FIG. 2 illustrates a cross-sectional view of a NexFET device according to one implementation of the disclosure.

FIG. 3 shows a cross-sectional view of a semiconductor die including two FET devices having a cross-talk according to an implementation of the disclosure.

FIG. 4A shows a top view of a wafer including a plurality of semiconductor dies each having two FET devices that are isolated by a trench according to one implementation of the disclosure.

FIG. 4B shows a cross-sectional view of a semiconductor die including two FET devices isolated by a trench according to one implementation of the disclosure.

FIG. 5 shows is a graph illustrating experimental results of utilizing a trench in a semiconductor die having two FET devices according to one implementation of the disclosure.

FIG. 6 displays a flowchart for steps of forming a trench on a semiconductor die including two FET devices according to one implementation of the disclosure.

FIG. 7 illustrates a cross-sectional view of a semiconductor package including two FET devices according to one implementation of the disclosure.

### DETAILED DESCRIPTION

In accordance with at least one aspect of the disclosure, two FET devices are formed on a substrate. Each of the two FET devices have separate gates and sources but share a common drain. A middle region of the substrate is used to form two channels for each of the two FET devices. A trench is formed within the middle region of the substrate to isolate the two channels. In an implementation, the trench is formed during the packaging operation of the dies using partial dicing techniques. The trench is filled with non-conductive material (e.g., molding material). The trench between the two channels reduces the cross-talk between the two FET devices, and therefore, increase the reliability of the IC.

Certain terms have been used throughout this description and claims to refer to particular system components. As one skilled in the art will appreciate, different parties may refer to a component by different names. This document does not intend to distinguish between components that differ in name but not function. In this disclosure and claims, the terms “including” and “comprising” are used in an open-ended fashion, and thus should be interpreted to mean “including, but not limited to . . . .” Also, the term “couple” or “couples” is intended to mean either an indirect or direct wired or wireless connection. Thus, if a first device couples to a second device, that connection may be through a direct connection or through an indirect connection via other devices and connections. The recitation “based on” is intended to mean “based at least in part on.” Therefore, if X is based on Y, X may be a function of Y and any number of other factors.

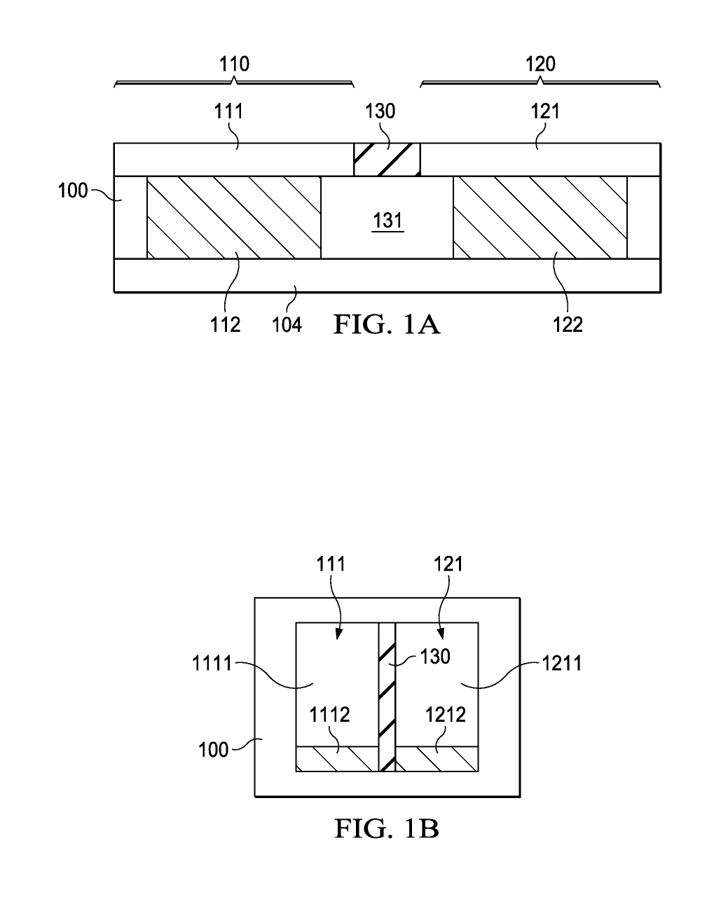

FIGS. 1A and 1B respectively show a cross-sectional view and a top view of a semiconductor die including two field-effect transistor (FET) devices. Referring to FIG. 1A, the FET devices 110 and 120 are formed on a substrate 100. The top portion 111 includes the gate contact(s) and the source contact(s) for the FET device 110. Similarly, the top portion 121 includes the gate contact(s) and the source contact(s) for the FET device 120. For example, referring to FIG. 1B, the regions 1111 and 1211 is used to place the source contact(s) and the regions 1112 and 1212 are used to provide the gate contact(s). The top portion 111 of the FET device 110 is separated from top portion 121 of the FET device 120 by an isolation diffusion (iso) region 130.

The substrate 100 also includes two channel regions 112 and 122 for the FET devices 110 and 120 respectively. The channel regions connect the top portions 111 and 121 to a common drain 104. In an example, the channel regions 112 and 122 are separated by a middle region 131. In an implementation, the middle region 131 is lightly doped or consists of intrinsic material (e.g., intrinsic silicon). The common drain 104 and the source region on the top portions 111 and 121 are heavily doped with the same type of dopants in an example. When one of the FET devices is on, carriers travel vertically from the source, under the gates, through the channel regions 112 and 122 to the common drain 104.

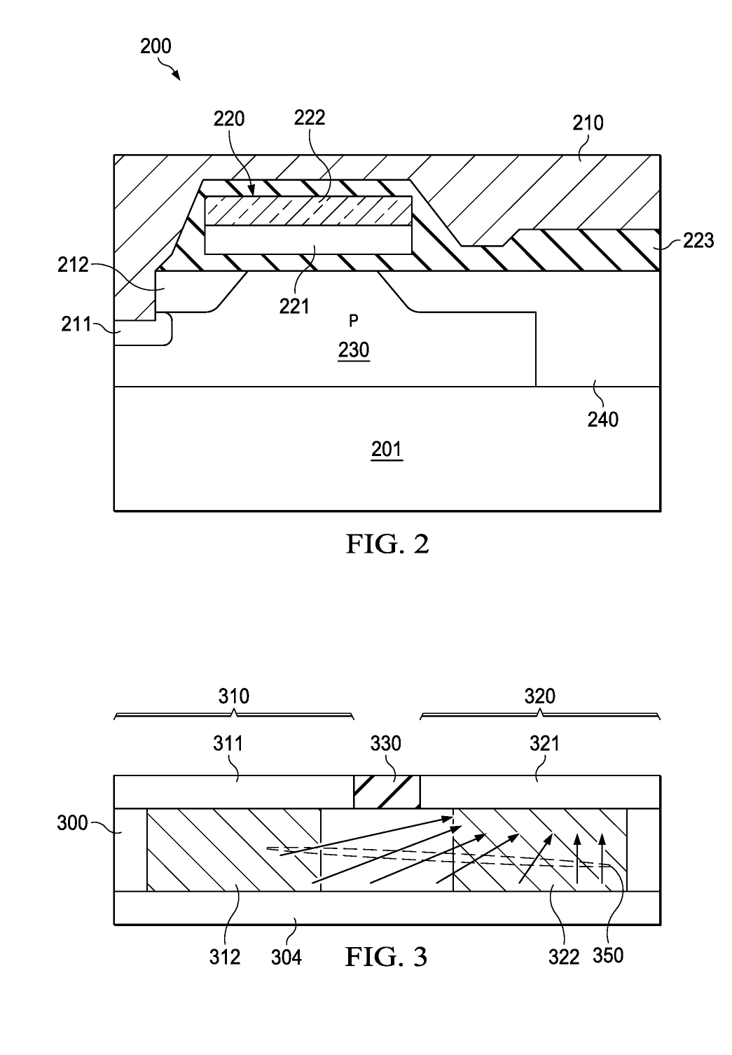

In one implementation, the FET devices 110 and 120 are MOSFET devices. In one example, the FET devices 110 and 120 are NexFET devices. Referring to FIG. 2, a cross-sectional view of a NexFET device according to one implement of the disclosure is shown. The NexFET device 200 includes a gate 220, which may be formed by a layer of Silicide 222 on top of a layer of polysilicon 221. Insulating materials 223 surround the gate 220 to insulate the gate from the rest of the substrate. The NexFET device 200 also includes a source metal layer 210 that is in contact with P++ region 211 and the source region 212. A channel region 230 is formed underneath the insulating material 223. The channel region 230 is in contact with the P++ region 211 and the drain region 240. The drain region 240 is in contact with the substrate 201, which serves as a drain contact for the other FET device on the die. For example, in one implementation, the common drain 104 in FIG. 1 is the same as the substrate 201 in FIG. 2.

FIG. 3 shows a cross-sectional view of a semiconductor die including two FET devices having a cross-talk. A cross-talk between the FET devices 310 and 320 occurs when one of the device's load is heavier than the other's. The current in a heavily loaded channel affects potential distribution of carriers in the other channel. For example, the FET device 310 may be intended to be turned off, and therefore, lightly loaded. At the same time, the FET device 320 may be turned on, and therefore, heavily loaded. In this scenario, as shown by arrows 350, the charges from the channel region 312 of the lightly loaded FET device 310 are pulled to the channel region 322 of the heavily loaded FET device 320. As such, an undesirable current may be produced on the FET device 310 when it is supposed to be turned off. Therefore, with increasing load on the highly loaded channel region 322, the current sense measurement accuracy of the lightly loaded channel region 312 degrades. The use of the terms “lightly loaded” and “highly loaded” describe the state of each FET device with respect to the other FET device on the die. Therefore, unless equal loads are used on both FET devices, one of the FET devices is always lightly loaded (or highly loaded) in compare to the other one.

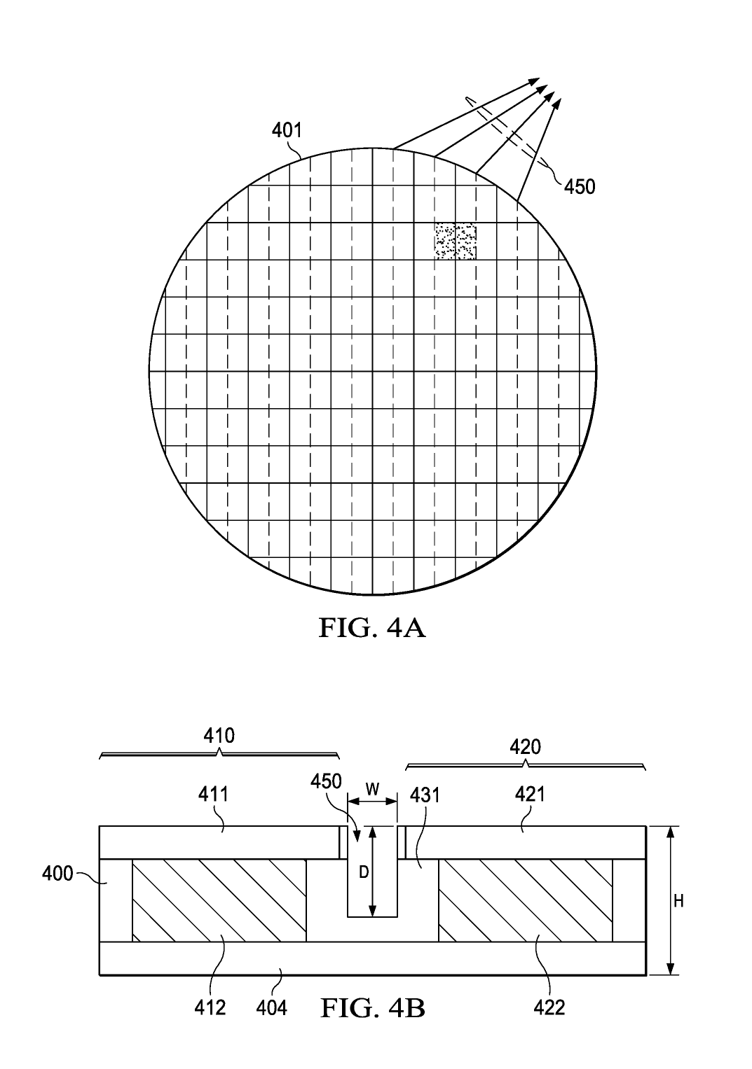

Present disclosure describes techniques of reducing the cross-talk phenomenon between two FET devices on a single die. FIG. 4A shows a top view of a wafer including a plurality of semiconductor dies each having two FET devices that are isolated by a trench. FIG. 4B shows a cross-sectional view of a semiconductor die including two FET devices isolated by a trench. Referring to FIG. 4A, in an implementation, the semiconductor dies (e.g., the semiconductor die of FIG. 4B) are arranged on the wafer 401 in rows and columns. To form a trench on each semiconductor die, a partial dicing operation is performed along one or more columns of the wafer 401 (shown by dashed lines 450). In an example, each continuous trench goes through a plurality of semiconductor dies within a column. The trenches are in parallel with the columns and perpendicular to the rows of the wafer 401.

Referring to FIG. 4B, the trench 450 is positioned within the middle region 430 of the substrate 400. The trench 450 at least partially isolates the first channel region 412 from the second channel region 422, and therefore, reduces the cross-talk between the two FET devices 410 and 420. The trench 450 has a depth D which is less than the height H of the wafer 401. In one example, the height H is the height of the middle region 431 of the substrate 400. In another example, the height H is the same as the height of the die after singulation operation of the wafer 401. In one implementation, the trench 450 may be filled with non-conductive material. For example, the trench 450 may be filled with molding material during the packaging of the die on a supporting case as explained further below.

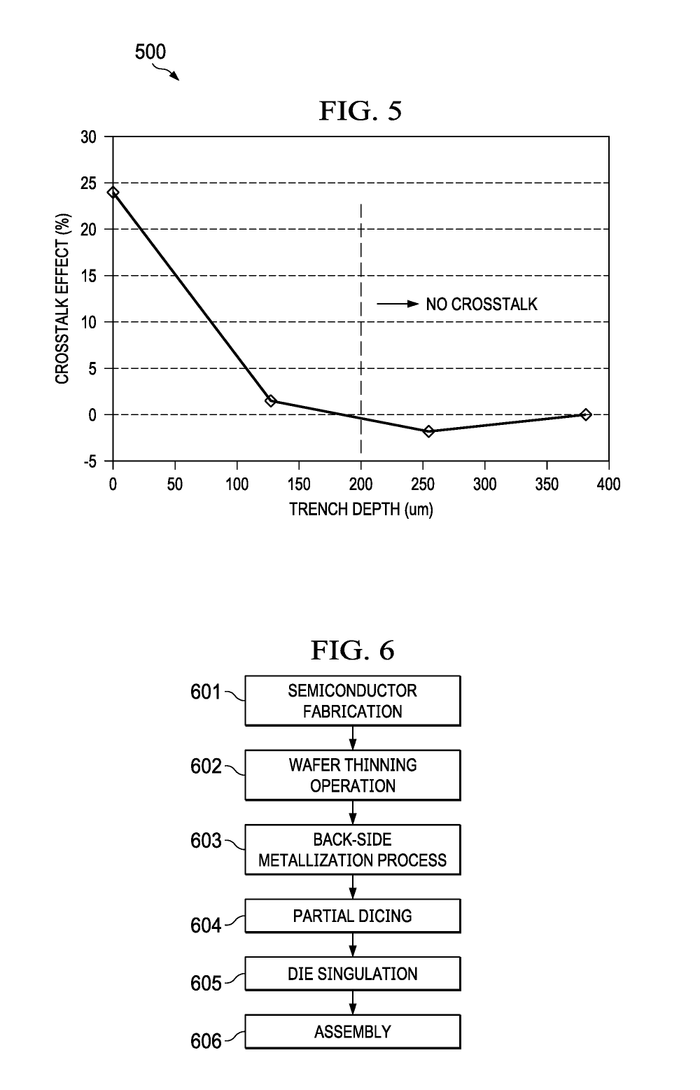

In an implementation, the appropriate size of the depth D depends on the load of the FET devices (i.e., higher load current requires deeper trench). In an example, the depth D of the trench 450 is at least half of the height H of the middle region 431 of the substrate 400. Referring to FIG. 5, the graph 500 displays experimental results of utilizing a trench in a semiconductor die having two FET devices as described above. The vertical axis plots the percentage of crosstalk effect as explained above with reference to FIG. 3. The horizontal axis displays the depth of the trench 450. In the example depicted in graph 500, the current from the lightly-loaded channel is 0.1 A while the currently from heavily-loaded channel is 10 A. The height H of the substrate is 370 um. As shown in graph 500, the percentage of cross-talk on the die decreases as the depth of the trench increases. However, at a depth of 200 um and more, the cross-talk is almost fully avoided. In an example, the width W of the trench 450 is between 40 um to 80 um.

FIG. 6 displays a flowchart 600 for steps of forming a trench in a semiconductor die including two FET devices. At block 601, a wafer including a large number of semiconductor dies is produced at the conclusion of a semiconductor fabrication process. The semiconductor fabrication process includes multiple steps of depositing material layers, patterning by photolithography techniques, and etching the layers to create the required shapes on a wafer. In an implementation, each semiconductor die includes two FET devices as described with reference to FIG. 3 above.

At block 602, the wafer goes through a thinning operation. The thinning operation is used to produce thinner semiconductor dies, and therefore, facilitates higher density of ICs in electronic devices. In an example, the thinning operation includes steps such as wafer backgrinding and back etching. Backgrinding operation consists of grounding down the backside of a wafer to a minimum thickness that still ensures a mechanical stability. In another example, thinning operations are done by chemical and plasma etching of the backside of the wafer. In an implementation, a wafer with a thickness of 750 um is thinned to a thickness of 380 um or less.

At block 603, the wafer goes through a back-side metallization (BSM) operation. The BSM operation is not always necessary for the semiconductor devices. However, it is especially useful for many high performance application dies such as power devices, microprocessors, and laser diodes. The BSM operation is needed to form backside contacts for subsequent die attachments. It is also helpful to improve dissipation of heat.

At block 604, a partial dicing operation is performed on the wafer. The partial dicing operation is used to generate the trench 450 of FIG. 4. In an implementation, the same technology and tooling as the full wafer dicing (discussed further with respect to block 605) is used to form trenches on the die. In an example, mechanical saw is used for the partial dicing operation. In other examples, laser-based techniques, also referred to as stealth dicing operation, is used. The wafer dicing technology is typically automated, however, to create the trenches feed speed (i.e., the speed at which the wafer passes through the blades), spindle revolution speed, and blade height may be modified.

As a result of partial dicing operation, while still attached to the wafer each die includes a trench isolating the channels of its FET devices. In other implementations, the trench may be formed after singulation operation of the wafer to a plurality of individual dies. In yet another implementation, the trench is actually formed during the semiconductor fabrication process of step 601.

At block 605, the wafer goes through die singulation operation. The die singulation operation may be similar to the partial dicing operation of the step 604 except that the cutting is all the way through the entire thickness of the wafer. In other implementations, wafer dicing may be achieved by scribing and mechanically breaking based on the partial scribe cut made by scribe tools. The resulting cut pieces of wafer are referred to as dies. A die could be in any shape or size that suits its design.

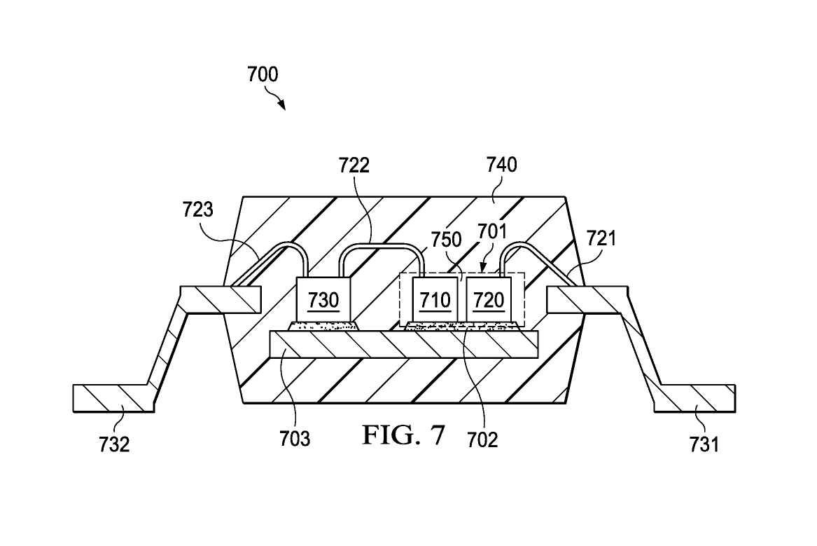

At block 606, each die is packaged in a supporting case that is designed to form electrical connection between the die and an underlying substrate (e.g., a printed circuit board (PCB). The supporting case also protects the dies from contaminations, moisture, and scratches. For example, referring to semiconductor package 700 of FIG. 7, the semiconductor die 701 includes two FET devices 710 and 720 that are attached to a lead frame 703 through a BSM layer 702. In an implementation, the semiconductor die 701 is attached to the lead frame 703 using a die attach layer. The trench 750 is formed between the two FET devices 710 and 720.

The semiconductor die 701 includes a plurality of bond pads on its top surface for communication of electrical signals. For example, the wire bond 721 connects the one or more bond pads of the semiconductor die 701 to the lead finger 731. Furthermore, the wire bond 722 connects the semiconductor die 750 to a controller 730 and the controller 730 is connected to lead finger 732 through the wire bond 723. The controller 730 regulates FET drive and monitors current in FET devices 710 and 720. In an implementation, the controller 730 also provides other functions such as shutdown, overvoltage detection, circuit short detection, and reverse polarity protection. In an example, the electrical signal is communicated from the semiconductor die 701 to an underlying substrate (e.g., PCB).

The semiconductor package 700 is covered in molding compound 740 (e.g., epoxy compound) to provide additional support for the components of the package. As such, the molding compound 740 covers the exposed surfaces of the semiconductor die 701. The molding compound 740 further covers the wire bonds 721, 722, 723 and at least a part of lead fingers 731 and 732. In an implementation, the trench 750 is filled with molding material while the molding material is deposited to cover the exposed surfaces of the semiconductor die 701. In other implementations, prior to encasing of the package, the trench is filled with non-conductive material that is different than the molding compound 740. In yet another example, the trench is filled with non-conductive material during the semiconductor fabrication process of step 601.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An integrated circuit, comprising:
a first FET formed on a substrate, comprising:
a first source,
a first gate, and
a first channel formed in the substrate to connect the first source to a common drain;
a second FET formed on the substrate, comprising:
a second source, and
a second gate,
a second channel formed in the substrate to connect the second source to the common drain; and
a trench formed in the substrate between the first channel and the second channel.

2. The integrated circuit of claim 1, wherein the trench is filled with molding materials.

3. The integrated circuit of claim 1, wherein the first FET and the second FET are connected through a middle region of the substrate.

4. The integrated circuit of claim 3, wherein the trench has a depth that is at least half of a height of the middle region of the substrate.

5. The integrated circuit of claim 1, wherein the first and second FET devices are NexFET devices.

6. The integrated circuit of claim 1, wherein the middle region of the substrate consists of intrinsic silicon while a portion of the substrate forming the first channel and the second channel is doped with charge carriers.

7. A method for fabricating semiconductor dies:
forming a wafer including one or more semiconductor dies, wherein at least one semiconductor die of the one or more semiconductor dies includes two FET devices and two channels associated with each FET devices;
thinning the wafer by performing backgrinding operation;
partially dicing the wafer to create a trench between the two channels of the at least one semiconductor die;
singulating the wafer to separate the at least one semiconductor die from a rest of the one or more semiconductor dies; and
attaching the at least one semiconductor die to a supporting case.

8. The method of claim 7, further comprises:
covering exposed surfaces of the at least one semiconductor die with molding compounds; and
filling the trench between the two channels of the at least one semiconductor die with non-conductive material.

9. The method of claim 8, wherein the non-conductive material is the molding compound, wherein the trench is filled with the molding compound while covering the exposed surface of the at least one semiconductor die.

10. The method of claim 7, wherein the partial dicing is performed by wafer saws.

11. The method of claim 7, wherein the partial dicing is performed by stealth dicing operation.

12. The method of claim 7, wherein the tow FET devices on the at least one semiconductor die are NexFET dies.

13. The method of claim 7, wherein a depth of the trench is at least half of a height of the semiconductor die.

14. A semiconductor package comprising:
a semiconductor die, wherein the semiconductor die includes two FET devices and two channels associated with each FET devices;
a lead frame attached to the semiconductor die through a layer of die attach; and
a trench formed between the two FET devices, wherein trench at least partially isolates the two channels of the semiconductor die.

15. The semiconductor package of claim 14, wherein the trench has a depth that is at least half of a thickness of the semiconductor wafer.

16. The semiconductor wafer of package 14, wherein the two FET devices are NexFET devices.

17. The semiconductor package of claim 14, wherein the trench is formed by a partial dicing operation.

18. The semiconductor package of claim 17, wherein the partial dicing operation is performed by a wafer saw.

19. The semiconductor package of claim 14, wherein the trench has a depth that is greater than a width of the trench.

20. The semiconductor package of claim 14, wherein the trench is filled with non-conductive material.
